(19) United States
(12) Patent Application Publication
(10) Pub. No.: US 2007/0037071 A1
(43) Pub. Date: Feb. 15, 2007

(54) Method for removing defect material of a lithography mask

(75) Inventors: Christoph Noelscher, Nurnberg (DE); Martin Verbeek, Munchen (DE); Christian Crell, Dresden (DE)

Correspondence Address: MORRISON & FOERSTER LLP, 1650 TYSONS BOULEVARD, SUITE 300, MCLEAN, VA, 22102, US

(73) Assignee: Qimonda AG, Munchen (DE)

(21) Appl. No.: 11/510,701

(22) Filed: Aug. 28, 2006

Related U.S. Application Data
(63) Continuation of application No. PCT/EP06/00660, filed on Jan. 26, 2006.

(30) Foreign Application Priority Data
Jan. 28, 2005 (DE) 10 2005004070.5

(51) Int. Cl. C23C 14/32; G21K 5/10; H01J 37/08; G03C 5/00; C23C 14/00; G03F 1/00

(52) U.S. Cl. 430/5; 204/192.24; 250/492.21; 430/394

(57) ABSTRACT

The present invention relates to a method for removing defect material in a transmissive region of a lithography mask having transmissive carrier material and absorber material. A first method step involves removing defective material and absorber material in a processing region. A second method step involves applying an absorbent material in an outer region, the outer region depending on the partial region of the processing region that was previously covered with absorber material.

### TECHNICAL FIELD OF THE INVENTION

The present invention relates to a method for removing defective material in a transmissive region of a lithography mask, and to a lithography mask having a transmissive region.

### BACKGROUND OF THE INVENTION

Photolithographic patterning methods are generally used for fabricating large-scale integrated electrical circuits having small structure dimensions on a semiconductor substrate wafer. In this case, a radiation-sensitive photoresist layer is applied to a substrate wafer surface to be patterned and is exposed with the aid of electromagnetic radiation through a lithography mask. During the exposure operation, mask structures which are predefined by mutually adjacent transmissive and absorbent regions of the lithography mask are imaged onto the photoresist layer with the aid of a lens system and transferred into the photoresist layer by means of a subsequent development process. The photoresist layer patterned in this way can be used directly as a mask in an etching process or an implantation doping for fabricating electronic circuit structures in the surface of the substrate wafer.

A principal objective of the semiconductor industry is to continuously increase performance by means of ever faster circuits, this being linked with miniaturization of the electronic structures. In order to fabricate smaller structures, there is primarily the possibility of changing to shorter wavelengths of the exposure radiation used. For economic reasons, however, it is simultaneously endeavoured to utilize the lithography technology respectively used for as long as possible before changing to the next shorter exposure wavelength in order to attain further structure miniaturizations. In order to increase the resolution limit for fabricating smaller structures with the exposure wavelength remaining the same, so-called “resolution enhancement techniques” (RET) are increasingly being used, therefore, in photolithography or microlithography. These include in particular the use of so-called phase shifting masks (PSM), which are also referred to as phase masks.

Compared with standard chromium masks or binary masks, in which the structures to be imaged are reproduced by means of a patterned absorbent chromium layer arranged on a transmissive carrier, phase masks differ in that they have two types of transmissive regions between which there is a phase difference of 180°. This results in a sharp light-dark transition in the exposure radiation transmitted through a phase mask at the edges of the mask structures, which leads to an improved resolution capability.

One significant type of phase masks is so-called alternating phase shifting masks (AltPSM), which have alternating transmissive regions having a phase of 0° and a phase or phase shift of 180°, between which are arranged absorbent regions provided with absorber material in each case. In this case, the transmissive regions having a phase shift of 180°, referred to hereinafter as phase shift regions, are generally etched into the transmissive carrier material of the phase masks, whereby a propagation time difference in the exposure radiation used and hence the desired phase shift of 180+ are obtained.

A main problem in the case of alternating phase shifting masks is residual residues of transmissive carrier material in the phase shift regions, which should actually be completely etched free in order to obtain the phase shift of 180°. These residues, referred to hereinafter as defect material, are primarily caused by excess residues of the absorber material or else particles which lie above the respective phase shift regions to be fabricated prior to the etching of the transmissive carrier material.

Such defects lying in or at the phase shift regions often bring about a phase of the exposure radiation of 0°. The exposure radiation is consequently extinguished at the edges of the defects on account of destructive interference, as a result of which the defects have a dark effect and are therefore harmful even with small lateral dimensions. The defects are particularly critical especially in narrowly delimited or narrow phase shift regions, which are formed for example as lines or trenches or contact holes, and also in so-called “180° phase assists”. Transparent or else partly transparent or non-transparent defects having a curved surface in trenches of the mask are likewise critical.

In order to avoid such defects, the absorbent regions of the phase masks, prior to the etching of the transmissive carrier material, are generally inspected with regard to excess absorber residues and these are repaired, if appropriate, by means of a focused ion beam. What is disadvantageous, however, is that residues of the absorber material can be overlooked and, moreover, between the inspection and the etching of the carrier material, particles may get onto phase shift regions of a phase mask that are to be fabricated, by means of which the defects are formed.

Furthermore, it is known to measure fabricated phase shift regions of alternating phase shifting masks with the aid of an atomic force microscope (AFM) and to plane away, that is to say remove layer by layer, disturbing defect material with the aid of the measuring tip of the atomic force microscope. The planed-away defect material is subsequently removed in a cleaning process. This procedure, which is also referred to as “nanomachining” and is described for example in M. Verbeek et al., “High precision mask repair using nanomachining”, pages 1 to 8, EMC 2002, and also in Y. Morikawa et al., “Alternating-PSM repair by nanomachining”, pages 18 to 20, Microlithography World, November 2003, can be applied effectively, however, only when enough travel distance exists on both sides of the plane direction. Therefore, the method cannot be used to eliminate defects in phase shift regions with restricted lateral space conditions such as, for example, in contact holes and at trench ends.

As an alternative, there is the possibility of removing defect material in quartz trenches with the aid of a focused ion beam. This method disadvantageously has an inadequate spatial resolution, however, which becomes apparent particularly in the case of small holes. Moreover, the transmittance of a phase shift region repaired in this way is reduced by implanted ions of the ion beam used. Furthermore, the use of a focused ion beam may result in a disturbing surface roughness of the bottom and also of the edges of the processed phase shift region.

### SUMMARY OF THE INVENTION

The present invention provides an improved method for removing defective material in a transmissive region of a lithography mask, and also a defect-free lithography mask.

In one embodiment of the invention, there is a method for removing defective material in a transmissive region of a lithography mask having transmissive carrier material and absorber material. In this case, a first method step involves removing defective material and inherently intact absorber material in a processing region, and a second method step involves applying an absorbent material in an outer region, the outer region depending on the partial region of the processing region that was previously covered with absorber material. As a result, the defect is eliminated and the desired absorption geometry is re-established.

In one aspect according to the invention, in a processing region, both defect material and absorber material are removed and, if appropriate, transmissive carrier material arranged below the absorber material, and subsequently applying absorbent material in an outer region in order again to form a predetermined transmissive region having a desired phase shift on the lithography mask. In this way, the method according to the invention affords the possibility of reliably removing a defect in a transmissive region even when there are restricted space conditions such as are present for example in holes or at trench ends. The method can be used in particular for eliminating defects in phase shift regions of alternating phase shifting masks, but can also be applied to other lithography masks such as binary masks, for example, for the purpose of removing defects.

In one preferred embodiment, a focused ion beam is used in the first method step for removing defective material and absorber material and also, if appropriate, transmissive carrier material. This embodiment enables simple and fast elimination of a defect in a transmissive region of a lithography mask. In this case, the relevant materials are preferably removed as far as or to below a plane which is predefined by the bottom of the transmissive region.

In one preferred embodiment, in the first method step, preferably with the aid of a focused ion beam, an auxiliary hole is formed adjacent to or in the vicinity of the transmissive region and defective material or defective material and absorber material and also, if appropriate, transmissive carrier material subsequently is removed with the aid of a microplane. The formation of an auxiliary hole creates a sufficient travel distance for the microplane used, which is for example the measuring tip of an atomic force microscope. Consequently, this embodiment of the method is suitable in particular for removing defective material in a transmissive region of a lithography mask having confined space conditions, for example at a trench end of a transmissive region present as a trench. On account of the use of a microplane, a transmissive region repaired in this way has a bottom and side areas having a planar and smooth surface and also straight edges. In the formation of the auxiliary hole, the relevant mask materials, in accordance with the embodiment described above, are preferably removed as far as or to below a plane which is predefined by the bottom of the transmissive region.

In accordance with an alternative preferred embodiment, in the first method step, preferably with the aid of a focused ion beam, two auxiliary holes are formed adjacent to and/or in the vicinity of opposite sides of the transmissive region. Defective material or defective material and absorber material and also, if appropriate, transmissive carrier material subsequently is removed with the aid of a microplane. This embodiment, too, can advantageously be used for removing a defect in a transmissive region with restricted space conditions such as are present in a narrow hole, for example, since a sufficient travel distance for the microplane is created by means of the two auxiliary holes.

It is also preferred to subject the lithography mask to an additional cleaning process after removal of the defective material or of the defective material and of the absorber material and also, if appropriate, of the transmissive carrier material with the aid of the microplane. In this way, the material or materials removed by the microplane is or are completely removed from the lithography mask.

If a focused ion beam is used for material removal, it can happen that ions from the ion beam are implanted in the transmissive region of the lithography mask, which results in a lowering of the transmittance of the repaired transmissive region. In order to compensate for this effect, in the second method step the absorbent material is applied in the outer region or in the auxiliary hole/holes in such a way as to form a transmissive region of the lithography mask that is enlarged compared with the original transmissive region. In order to be able to compensate for the reduction of transmission, the region to be etched away is, if appropriate, chosen from the outset to be somewhat greater than would be necessary solely for removal of the defect present. After the above-described application of the absorber material, the defective material has then been removed and, moreover, the local transmission which is optically effective in the imaging is close to the ideal state.

On the other hand, there is the possibility for a transmissive region of a lithography mask that is repaired at an edge to exhibit an increased transmission of exposure radiation compared with a defect-free ideal transmissive region. This effect is caused by a reduced scattering of the exposure radiation at the edge on account of an edge structure which is present after the defect elimination and deviates from an ideal edge structure. In such a case, it is preferred, in the second method step, to apply the absorbent material in the outer region in such a way as to form a transmissive region of the lithography mask that is reduced in size compared with the original transmissive region, in order to compensate for this effect.

With regard to the two last-mentioned opposing embodiments of the invention, it is preferable, if appropriate, to simulate the optical imaging behaviour of the lithography mask prior to carrying out the second method step. In this way, the absorbent material may be applied in accordance with a desired optimum imaging behaviour. In order to determine the parameters of the simulation, the mask geometry is measured before and, if appropriate, during the repair by methods according to the prior art, that is to say e.g. by means of an optical microscope (AIMS), electron microscope, ion microscope or atomic force microscope.

In another embodiment of the invention, there is a lithography mask having a transmissive region, in which defective material is removed by the method according to the invention or one of the preferred embodiments. Since, with the aid of the method or the preferred embodiments, defects can be removed reliably and efficiently in particular also in transmissive regions with confined space conditions, such a defect-free lithography mask is distinguished by a good optical imaging behaviour.

In general, such a lithography mask has a transmissive region bordered by one or more absorber materials with respect to a surface of the lithography mask, the absorber material or absorber materials being arranged in different horizontal planes on the lithography mask.

### BRIEF DESCRIPTION OF THE DRAWINGS

The invention is explained in more detail below with reference to the figures, in which:

FIGS. 1 to 4 show an exemplary transmissive phase shift region of a phase mask having a defect and the removal thereof in accordance with the invention in each case in plan view and in a lateral sectional illustration.

FIGS. 5 to 8 show a another exemplary transmissive phase shift region of a phase mask having a defect and the removal thereof in accordance with the invention in each case in plan view and in a lateral sectional illustration.

FIGS. 9 to 11 show the removal of the defect of the phase shift region of FIG. 5 in accordance with the invention in each case in plan view and in a lateral sectional illustration.

### DETAILED DESCRIPTION OF THE INVENTION

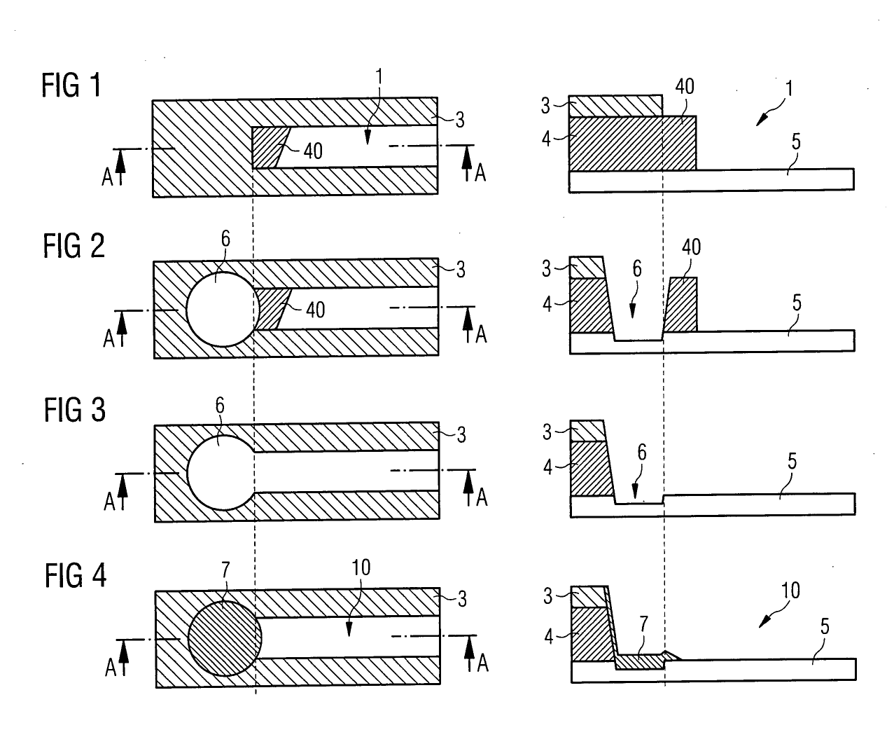

FIG. 1 shows an exemplary transmissive phase shift region of an alternating phase shifting mask, referred to hereinafter as transmissive region 1, in a schematic plan view and sectional illustration. In this case, and also in the subsequent figures, the sectional line for the sectional illustration runs along the sectional line AA of the corresponding plan view. The transmissive region 1 is present as a trench in a surface of the phase mask and, as can be discerned from the plan view of FIG. 1, is bordered with respect to the surface by an absorber material 3 such as, for example, chromium. The transmissive region 1 has a width of 400 nm, by way of example.

The further construction of the phase mask can be discerned from the lateral sectional illustration of FIG. 1. The phase mask has a layer of a transmissive carrier material 5 and also a further layer of a transmissive carrier material 4, the further layer being arranged between the absorber 3 and the carrier material 5. The carrier materials 4, 5 are usually the same transmissive material such as, for example, quartz.

In the context of the fabrication of the phase mask, the carrier material 4 not covered by the absorber material 3 is etched away as far as the surface of the carrier material 5 in order to bring about the above-described phase shift of 180° of an electromagnetic radiation used during a lithographic exposure. The absorber 3 has a thickness of 80 nm, by way of example. The layer of the transmissive carrier material 4 has a thickness of 170 nm, by way of example, in order to bring about a phase shift of 180° at an exposure wavelength of 193 nm.

FIG. 1 also shows a defect 40 at a trench end of the transmissive region 1, which defect emerges from a residue of carrier material 4 that has not been etched away. Such a defect 40 is caused for example by an excess residue of the absorber material 3, or a particle, which is arranged on the carrier material 4 prior to etching. The defect 40 leads for example to a phase of an exposure radiation of only 0°, whereby the exposure radiation is extinguished at the edge of the defect 40 on account of destructive interference. Consequently, the defect 40 brings about a disturbing darkening of the edge or of the trench end during a lithographic exposure. Corresponding darkening effects may also occur in the case of phase shifts that differ from 0°, on account of a defect or in the event of scattering at the defect.

In order to remove the defect or defective material 40, in accordance with a first embodiment of a method according to the invention, as illustrated in FIG. 2, firstly an auxiliary hole 6 is etched—with the aid of a focused ion beam—in an outer region in the vicinity of the defect 40 adjacent to the transmissive region 1. In this case, absorber material 3 and carrier material 4 and also, as can be seen from FIG. 2, if appropriate, a small part of the carrier material 5 are removed.

Afterwards, as illustrated in FIG. 3, the defect material 40 is removed with the aid of a microplane (not illustrated). In this case, the defect material 40 is preferably pushed in the direction of or into the auxiliary hole 6. By way of example, the measuring tip of an atomic force microscope functions as the microplane. The atomic force microscope may simultaneously be used beforehand for measuring the transmissive region 1 and also the defect 40. Afterwards, as illustrated in FIG. 4, a layer of an absorbent material 7 having a thickness of 40 nm, by way of example, is applied to the uncovered outer region or the auxiliary hole 6. Carbon or a metal such as chromium is preferably used as the absorbent material 7, and is deposited in the outer region with the aid of a standard process, by way of example. A new transmissive region 10 of the phase mask is formed in this way.

As can be discerned from the dotted line of FIGS. 1 to 4, the absorbent material 7 projects into the original transmissive region 1, as a result of which the transmissive region 10 is formed such that it is somewhat smaller laterally than the original transmissive region 1. This compensates for an increased transmission of exposure radiation during an exposure. The increased transmission is caused by a reduced scattering of the exposure radiation at the repaired, defect-free trench end of the transmissive region 10 on account of an edge structure which is changed as a result of the defect elimination and deviates from an ideal edge structure.

If appropriate, it is preferable to subject the phase mask to an additional cleaning process prior to the application of the absorbent material 7. In this way, the defect material 40 removed by the microplane is completely removed from the phase mask, so that the absorbent material 7 is applied to the carrier material 5 and not to defect material situated in the auxiliary hole 6 or at the edge of the auxiliary hole 6. If appropriate, the displaced defect material can also be covered with absorber if the repaired structure is then still stable to withstand a later cleaning, or such a cleaning can be dispensed with.

Instead of forming the auxiliary hole 6 adjacent to the transmissive region as illustrated in FIG. 2, it is also possible to form the auxiliary hole at a small distance in the vicinity of the transmissive region. Consequently, with the aid of the microplane, absorber material 3 present between the defect 40 and the auxiliary hole and carrier material 4 situated below the absorber material 3 are also additionally removed besides the defect material 40.

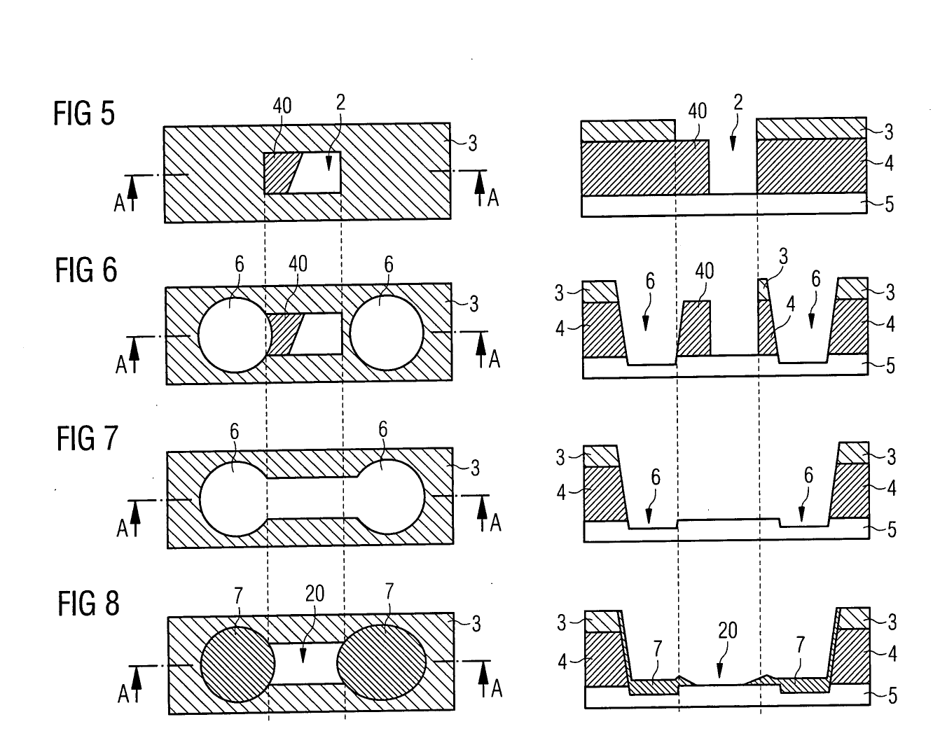

Additionally, there is the possibility of forming, instead of one auxiliary hole 6, two auxiliary holes adjacent to and/or in the vicinity of opposite sides of the transmissive region 1. These auxiliary holes are formed for example on the two longitudinal sides of the transmissive region 1 in the vicinity of the defect 40. The formation of two auxiliary holes is preferable particularly for defect elimination in the case of a transmissive region of a phase mask that is present as a hole having relatively small lateral dimensions. This is explained in more detail with reference to the subsequent FIGS. 5 to 8.

FIG. 5 shows another exemplary transmissive phase shift region of a phase mask, referred to hereinafter as transmissive region 2, with a defect 40 which again emerges from a residue of carrier material 4 that has not been etched away at an end of the transmissive region 2. The transmissive region 2, which is formed as a hole, is correspondingly bordered by an absorber material 3 such as chromium, by way of example, with respect to a surface of the phase mask and has for example a width of 400 nm and a length of 800 nm.

Two layers made of transmissive carrier material 4, 5, both of which usually consist of quartz, are again arranged below the absorber 3. The absorber 3 once again has a thickness of 80 nm, by way of example. The thickness of the layer of the transmissive carrier material 4 is again 170 nm, by way of example, in order to bring about a phase shift of the exposure radiation of 180° at an exposure wavelength of 193 nm.

In order to remove the defect 40, as illustrated in FIG. 6, two auxiliary holes 6 are formed with the aid of a focused ion beam in an outer region on opposite sides of the transmissive region 2. Absorber material 3 and carrier material 4 and also, if appropriate, a small part of the carrier material 5 are removed during the production of the auxiliary holes 6.

It can furthermore be seen from FIG. 6 that the left-hand auxiliary hole 6 is formed for example adjacent to the transmissive region 2 and the right-hand auxiliary hole 6 is formed for example at a small distance in the vicinity of the transmissive region 2. It goes without saying that there is the possibility of forming both auxiliary holes 6 together adjacent to or in the vicinity of the transmissive region 2.

Afterwards, as illustrated in FIG. 7, the defect material 40 and also absorber material 3 situated at the edge of the right-hand auxiliary hole 6 and carrier material 4 arranged underneath are removed with the aid of a microplane (not illustrated), which may again be the measuring tip of an atomic force microscope. In this case, the relevant materials are preferably pushed in the direction of or into the auxiliary holes 6.

After an optional process of cleaning the phase mask, in which the materials removed with the aid of the microplane are completely eliminated, the outer region or the auxiliary holes 6, as illustrated in FIG. 8, is or are covered with a layer of an absorbent material 7 such as carbon or metal, by way of example, so that a transmissive region 20 is provided. The layer of the absorbent material 7 again has a thickness of 40 nm, by way of example.

It can be seen from the dotted lines illustrated in FIGS. 5 to 8 that the transmissive region 20 is again formed such that it is smaller than the original transmissive region 2. An increased transmission brought about by a reduced scattering of exposure radiation at the edge of the transmissive region 20 is once again compensated for in this way.

As can be discerned from FIGS. 4 and 8, the repaired phase masks in each case have a transmissive region 10 and 20, respectively, which, with respect to a surface of the phase masks, is bordered by one absorber material or, for the case where the applied absorbent material 7 differs from the absorber material 3, by a plurality of absorber materials. In this case, the absorber material or absorber materials is or are arranged in different horizontal planes on the phase masks.

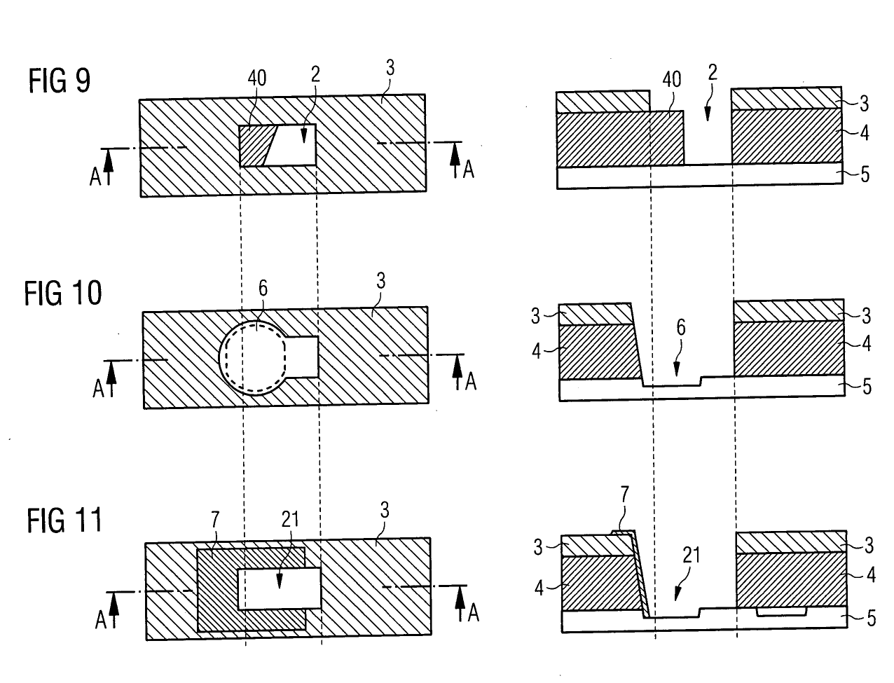

FIGS. 9 to 11 show the removal of the defect 40 in the transmissive region 2—formed as a hole—of the phase mask in accordance with a third embodiment of a method according to the invention, in which the use of a microplane is dispensed with. In this case, a focused ion beam is used to remove defect material 40, absorber material 3 and underlying carrier material 4 and, if appropriate, a small part of the carrier material 5, as illustrated in FIG. 10. An auxiliary hole 6 that takes up a relatively large partial region of the transmissive region 2 is formed in this way. After an optional process of cleaning the phase mask, as shown in FIG. 11, absorbent material 7 is again applied in an outer region in order to form a transmissive region 21 of the phase mask.

This third embodiment of a method according to the invention can likewise be used for defect elimination on transmissive regions having a different geometry. The defect 40 in the transmissive region 1 present as a trench as illustrated in FIG. 1 could also be removed in this way, by way of example.

It can be discerned from the dotted lines of FIGS. 9 to 11 that the transmissive region 21 is formed such that it is somewhat larger laterally compared with the original transmissive region 2. A reduced transmission of exposure radiation in the transmissive region 21 is compensated for in this way. The reduced transmission is caused by ions from the ion beam that are implanted in the transmissive region 21, the ion beam being used, as described above, for material removal in a relatively large partial region of the original transmissive region 2.

In principle, it is preferable to calculate the optical imaging behaviour of the phase mask in advance with the aid of simulations prior to applying the absorbent material 7. On the basis of these simulations, the absorbent material 7 can subsequently be applied in accordance with a desired optimum imaging behaviour of the phase mask, with the result that a transmissive region that is enlarged or else reduced in size compared with the original transmissive region is formed. It is also possible to form a transmissive region matching the dimensions of the original transmissive region.

If appropriate, it is additionally preferable, on a phase mask repaired with the aid of the method according to the invention or the embodiments described, prior to a lithography use, to measure an intensity distribution—referred to as an “aerial image”—of an exposure radiation after radiating through the phase mask and a lens system, and thereby to check the imaging behaviour of the phase mask. A customary “aerial image measuring system” (AIMS) can be used for this purpose.

Further embodiments are conceivable besides the embodiments of the method which have been described with reference to the figures. By way of example, it is conceivable, in a first method step, to remove defective and absorber material and no transmissive carrier material situated below the absorber in a processing region.

Furthermore, the method according to the invention or the embodiments described can be used not only for the removal of defective material in transmissive phase shift regions of alternating phase shifting masks. The method or the embodiments described can also be used for defect or material removal in transmissive regions having a phase of 0° and also, in principle, for material removal or else for the removal of particles in transmissive regions of other lithography masks such as, for example, binary lithography masks or reflective EUV masks.

What is claimed is:

1. A method for removing defective material in a transmissive region of a lithography mask having transmissive carrier material and absorber material, comprising:
removing defective material and absorber material in a processing region; and
applying an absorbent material in an outer region, the outer region depending on a partial region of the processing region previously covered with absorber material.

2. The method according to claim 1, wherein a focused ion beam is used for removing the defective material and absorber material.

3. The method according to claim 1, wherein during removing, an auxiliary hole is formed adjacent to or in a vicinity of the transmissive region and the defective material or defective material and absorber material are removed with aid of a microplane.

4. The method according to claim 1, wherein during removing, two auxiliary holes are formed adjacent to and/or in a vicinity of opposite sides of the transmissive region and defective material or defective material and absorber material are removed with aid of a microplane.

5. The method according to claim 3, wherein a focused ion beam being used for auxiliary hole formation.

6. The method according to claim 3, wherein the lithography mask is subjected to an additional cleaning process after removal of the defective material or of the defective material and the absorber material with aid of the microplane.

7. The method according to claim 1, wherein during applying, the absorbent material is applied in the outer region to form another transmissive region of the lithography mask that is enlarged compared with the transmissive region.

8. The method according to claim 1, wherein during applying, the absorbent material is applied in the outer region to form another transmissive region of the lithography mask that is reduced in size compared with the transmissive region.

9. The method according to claim 1, wherein carbon or metal is used as absorbent material.

10. A lithography mask comprising a transmissive region, in which defective material is removed by:
removing defective material and absorber material in a processing region; and
applying an absorbent material in an outer region, the outer region depending on a partial region of the processing region previously covered with absorber material.

11. The lithography mask according to claim 10, further comprising at least one auxiliary hole adjacent to or in a vicinity of the transmissive region.

12. A lithography mask comprising a transmissive region bordered by one or more absorber materials with respect to a surface of the lithography mask, the absorber material or absorber materials arranged in different horizontal planes on the lithography mask.
